(19) United States
(12) Patent Application Publication
(10) Pub. No.: US 2026/0258913 A1
(43) Pub. Date: Sep. 3, 2026

(54) GAS SUPPLY SYSTEM AND SEMICONDUCTOR MANUFACTURING APPARATUS

(71) Applicant: Tokyo Electron Limited, Tokyo (JP)

(72) Inventor: Masami SAKURAI, Fuchu City (JP)

(21) Appl. No.: 19/540,953

(22) Filed: Feb. 16, 2026

(30) Foreign Application Priority Data
Feb. 28, 2025 (JP) 2025-031177

(51) Int. Cl. F17D 1/02; F16L 23/16; F16L 53/35; H10P 72/00

(52) U.S. Cl. CPC F17D 1/02; F16L 23/16; F16L 53/35; H10P 72/0421

(57) ABSTRACT

A gas supply system including a gas box housing in which a precursor container accommodating a gas precursor is disposed, at least one pipe passing through a through-hole in the gas box housing, through which a fluid flowing into the gas box housing from outside flows, or a fluid flowing out of the gas box housing to the outside flows, and a block member installed in the through-hole and including a pipe surrounding portion configured to integrally surround an inner pipe portion that is a portion of the pipe inside the gas box housing and an outer pipe portion that is a portion of the pipe outside the gas box housing. While the pipe surrounding portion is inserted into a gap between an inner peripheral surface of the through-hole and an outer peripheral surface of the pipe, the block member is fixed to the gas box housing.

### CROSS-REFERENCE TO RELATED APPLICATION

This application is based upon and claims the benefit of priority from Japanese Patent Application No. 2025-031177, filed on Feb. 28, 2025, the entire contents of which are incorporated herein by reference.

### TECHNICAL FIELD

The present disclosure relates to a gas supply system and a semiconductor manufacturing apparatus.

### BACKGROUND

For example, in a semiconductor manufacturing apparatus that performs processing on a substrate, there is a step of supplying a gas to a processing container to perform substrate processing. A processing gas used for processing the substrate is supplied into the processing container via piping. Patent Document1 proposes a gas supply system that prevents liquefaction of a gas that is liable to be liquefied, thereby supplying the gas from a gas container to a processing container.

### Prior Art Documents

### Patent Documents

Patent Document 1: 2020-141038

### SUMMARY

According to one embodiment of the present disclosure, there is provided a gas supply system including: a gas box housing in which a precursor container accommodating a gas precursor is disposed; at least one pipe passing through a through-hole in the gas box housing, through which a fluid flowing into the gas box housing from outside flows, or a fluid flowing out of the gas box housing to the outside flows; and a block member installed in the through-hole, and including a pipe surrounding portion configured to integrally surround an inner pipe portion that is a portion of the pipe inside the gas box housing and an outer pipe portion that is a portion of the pipe outside the gas box housing, wherein, in a state where the pipe surrounding portion is inserted into a gap between an inner peripheral surface of the through-hole and an outer peripheral surface of the pipe passing through the through-hole, the block member is fixed to the gas box housing to block the gap.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view illustrating one embodiment of a semiconductor manufacturing apparatus including a gas supply system.

FIG. 2 is a plan view illustrating a configuration example of a precursor container and a gas box housing provided in the gas supply system.

FIG. 3 is a vertical sectional view illustrating a configuration example of the precursor container.

FIG. 4 is a vertical sectional side view illustrating a first comparative embodiment.

FIG. 5 is a vertical sectional side view illustrating a second comparative embodiment.

FIG. 6 is a vertical sectional side view illustrating a part of a gas supply system according to a first embodiment.

FIG. 7 is a perspective view illustrating a configuration example of a block member provided in the gas supply system.

FIGS. 8A to 8C are front views illustrating a configuration example of a flange portion of the block member and a seal member.

FIG. 9 is a vertical sectional side view illustrating a part of a gas supply system according to a second embodiment.

### DETAILED DESCRIPTION

### Semiconductor Manufacturing Apparatus

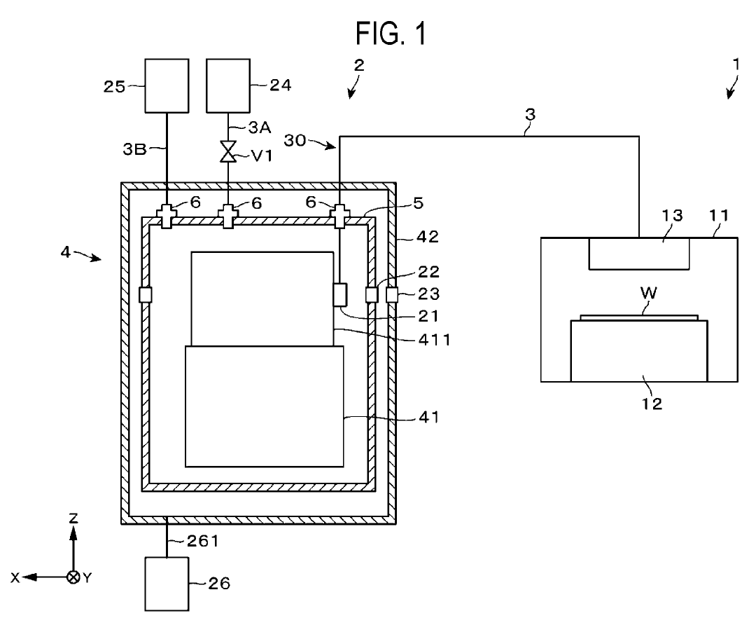

A configuration example of a semiconductor manufacturing apparatus 1 including a gas supply system 2 of the present disclosure will be described with reference to FIG. 1. FIG. 1 is a vertical sectional side view schematically illustrating the semiconductor manufacturing apparatus 1.

As illustrated in this drawing, the semiconductor manufacturing apparatus 1 includes a processing container 11 that stores and processes a semiconductor wafer (hereinafter referred to as “wafer”) W, which is a substrate for manufacturing semiconductors, and a placement table 12 on which the wafer W is placed is provided in the interior of the processing container 11.

A shower head 13 is disposed in a region facing the placement table 12 inside the processing container 11. A processing gas is supplied from the gas supply system 2 to the shower head 13 via a processing gas supply pipe 3, and the shower head 13 is configured to discharge the processing gas in a shower-like manner toward the wafer W on the placement table 12. Hereinafter, the processing gas supply pipe 3 may also be referred to simply as the “pipe 3”.

### Outline of Gas Supply System

Next, an outline of the gas supply system 2 will be described with reference to FIGS. 1 to 3. The gas supply system 2 includes a gas box 4, the processing gas supply pipe 3 that is a pipe for discharging a fluid outward from the gas box 4, and a block member 6 provided at a connection point between the pipe 3 and the gas box 4. Further, the gas box 4 includes a precursor container 41 that accommodates a liquid serving as a source for a gas precursor, a gas box housing 5 provided so as to surround the precursor container 41, and an outer housing 42 provided so as to surround the gas box housing 5. In FIGS. 1 to 3, a front-rear direction is defined as an “X direction”, a left-right direction horizontally intersecting the front-rear direction is defined as a “Y direction”, and an up-down direction is referred to as a “Z direction”.

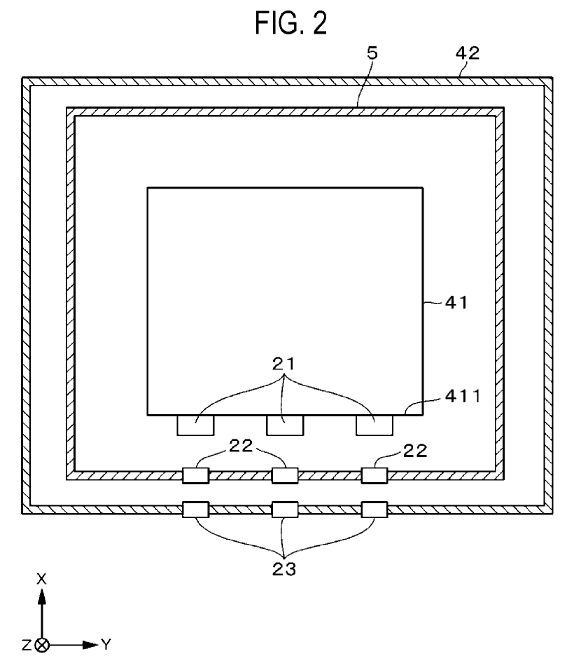

The precursor container 41 is provided with the processing gas supply pipe 3 and a valve 21 for opening and closing the pipe 3, and the valve 21 is configured to be opened and closed from the outside of the gas box housing 5 and the outer housing 42. The precursor container 41, the gas box housing 5, and the outer housing 42 are each formed, for example, in a rectangular shape in a plan view, as illustrated in FIG. 2. The valve 21 is provided on a sidewall 411 of the precursor container 41. Openings (not illustrated) are formed in wall portions of the gas box housing 5 and the outer housing 42 that face the valve 21 to open and close the valve 21 from the outside. These openings are respectively blocked by seal members 22 and 23.

The gas box housing 5 is connected to a supply source 24 for an inert gas such as a nitrogen (N₂) gas via a supply pipe 3A provided with a valve V1, and is also connected to an exhauster 25, which includes an exhaust pump and a valve, via a first exhaust pipe 3B. The supply and exhaust of the N₂ gas are performed to/from the interior of the gas box housing 5, which is adjusted to a preset pressure. Further, the outer housing 42 is connected, via a second exhaust pipe 261, to an exhaust line of a factory in which the semiconductor manufacturing apparatus 1 is installed, or to an exhauster 26, which includes an exhaust pump and a valve. A space between the gas box housing 5 and the outer housing 42 is exhausted and adjusted to a pressure (negative pressure) lower than the internal pressure of the gas box housing 5.

Since the interior of the gas box housing 5 is filled with the N₂ gas, the oxygen (O₂) concentration therein is maintained at a low level. Therefore, in a case where there is a concern for a gas generated inside the precursor container 41 to react with the atmosphere like a spontaneously ignitable material, even if the gas leaks from the precursor container 41 or the valve 21, ignition inside the gas box housing 5 is prevented. Further, even if gas leakage occurs, the leaked gas is exhausted together with the N₂ gas, thereby providing a high level of safety.

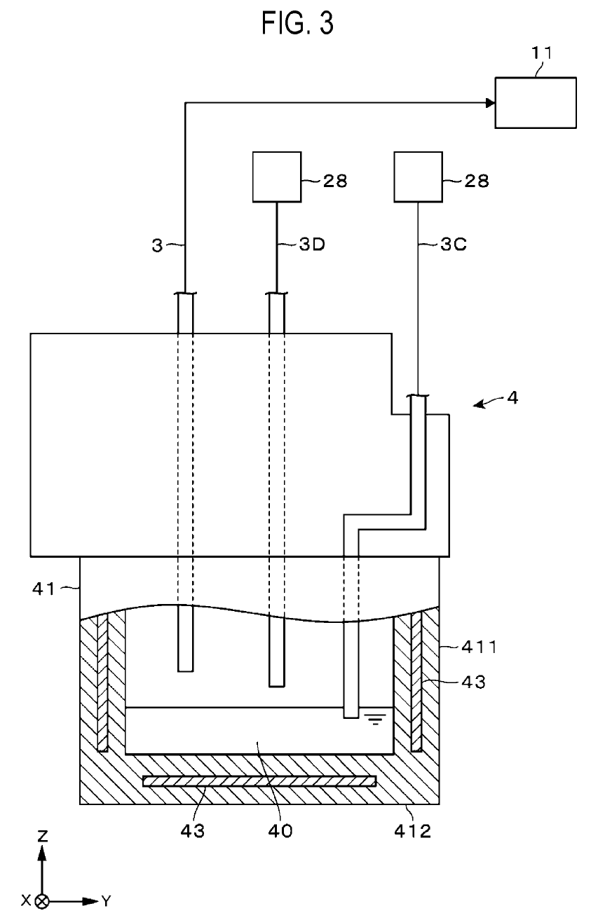

As illustrated in FIG. 3, the precursor container 41 accommodates, for example, a liquid 40 serving as a gas precursor, in the interior thereof, and includes a heater 43 for heating the liquid 40. For example, the heater 43 is embedded in the sidewall 411 or a bottom wall 412 of the precursor container 41. Further, in addition to the processing gas supply pipe 3, the precursor container 41 is connected to a first pipe 3C for supplying the liquid 40 from a reservoir 27 to the precursor container 41, and to a second pipe 3D for supplying a carrier gas, which is an inert gas, from a supply source 28 to the precursor container 41. For example, an argon (Ar) gas is used as the carrier gas.

Then, in the semiconductor manufacturing apparatus 1, the liquid 40 heated by the heater 43 is vaporized by the supply of the carrier gas to generate a processing gas in the precursor container 41 of the gas box 4. Then, the processing gas, together with the carrier gas, is discharged in a shower-like manner from the shower head 13 toward the wafer W placed on the placement table 12 via the processing gas supply pipe 3, thereby performing a predetermined process. Examples of the process performed on the wafer W include etching, film formation, and ashing.

The processing gas is generated by vaporizing the gas-precursor liquid 40 inside the precursor container 41 in this manner, and it is desirable that the processing gas supply pipe 3 be heated in order to prevent liquefaction or solidification of the gas, thereby supplying the gas up to the processing container 11. The processing gas supply pipe 3 is connected to the precursor container 41 via the gas box housing 5 and the outer housing 42. Therefore, openings for inserting the processing gas supply pipe 3 are formed in the gas box housing 5 and the outer housing 42. On the other hand, when the gas generated inside the precursor container 41 leaks, it is necessary to prevent further gas leakage from the interior of the gas box housing 5. From this viewpoint, there is a demand for a configuration in which the processing gas supply pipe 3 may be heated while maintaining the airtightness of the gas box housing 5.

### First Comparative Embodiment

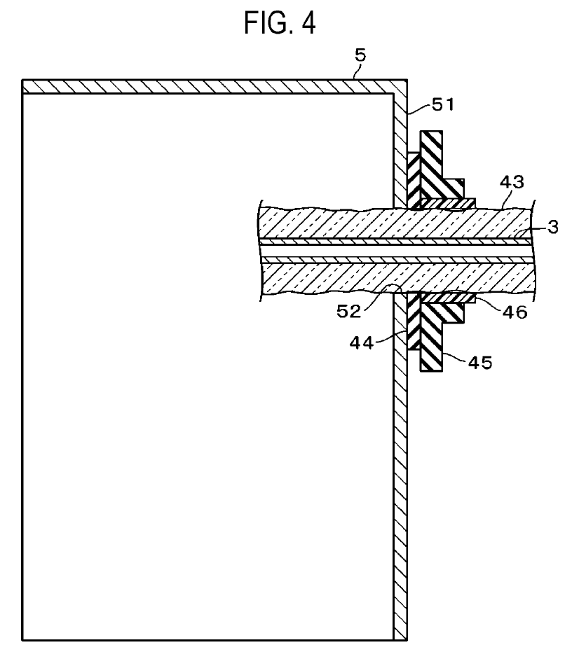

To address the above issue, for example, a comparative embodiment configuration illustrated in FIG. 4 may be conceived. FIG. 4 is a vertical sectional side view illustrating a connection point between the gas box housing 5 and the processing gas supply pipe 3. In FIG. 4, reference numeral 52 denotes a through-hole formed in an outer wall 51 of the gas box housing 5, and the processing gas supply pipe 3 is illustrated as being provided so as to pass through the through-hole 52.

It is assumed that the processing gas supply pipe 3 is heated by winding a tape heater 43 around an outer periphery thereof. The tape heater 43 includes, for example, a flexible material such as cloth or resin, and even when a bent portion is formed in the pipe 3, the tape heater 43 may be easily wound around such a portion, thereby enabling uniform heating. On the other hand, when the tape heater 43 is provided throughout the pipe 3 in this manner, as illustrated in FIG. 4, a gap between an inner peripheral surface of the through-hole 52 of the gas box housing 5 and an outer peripheral surface of the processing gas supply pipe 3 is blocked by the tape heater 43. Then, for example, a configuration may be conceived in which a fixing member 45 is provided on the outer wall around the through-hole 52 via a seal member 44, and the processing gas supply pipe 3 is fixed to the through-hole 52 by the fixing member 45. In this case, a heat insulating material 46 is also disposed between the tape heater 43 and the fixing member 45.

In this configuration, it is necessary to route the pipe 3, around which the tape heater 43 has been wound, through the through-hole 52 of the gas box housing 5. However, the winding of the tape heater 43 around the pipe 3 is manually performed by an operator. Therefore, assembly accuracy depends on the operator, and the sealing performance of the through-hole 52 may vary significantly. Further, a surface of the tape heater 43 is made of a flexible material such as cloth or resin, and when an attempt is made to fasten and fix the tape heater 43 using the fixing member 45, a gap is likely to be formed between the tape heater 43 and the through-hole 52. Therefore, it is presumed to be difficult to block, with high accuracy, the gap formed between the inner peripheral surface of the through-hole 52 and the outer peripheral surface of the pipe 3 so as to maintain the airtightness inside the gas box housing 5.

### Second Comparative Embodiment

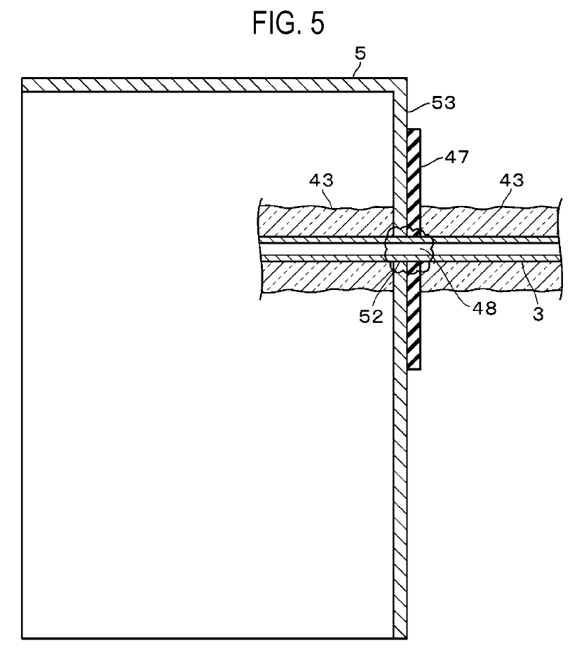

In view of the above, as illustrated in FIG. 5, a configuration may also be conceived in which the flexible tape heater 43 is not provided between the through-hole 52 and the pipe 3, and the gap between the through-hole 52 and the pipe 3 is designed to be as small as possible. In this configuration, the pipe 3 inside the gas box housing 5 and the pipe 3 outside the gas box housing 5 are each heated by the tape heater 43 wound around the outer periphery thereof. Further, a seal member 47 is provided around the through-hole 52 on an outer wall surface 53 of the gas box housing 5 (an outer surface of the outer wall 51) to ensure airtightness.

However, the tape heater 43 is not able to be wound around a region 48 surrounded by a solid line in FIG. 5 in the vicinity of the through-hole 52, i.e., around a connection point between the through-hole 52 and the pipe 3. Therefore, there is a concern that the temperature of the pipe 3 decreases in this region 48, which may cause liquefaction or solidification of the gas passing through the region 48, resulting in generation of particles.

### First Embodiment

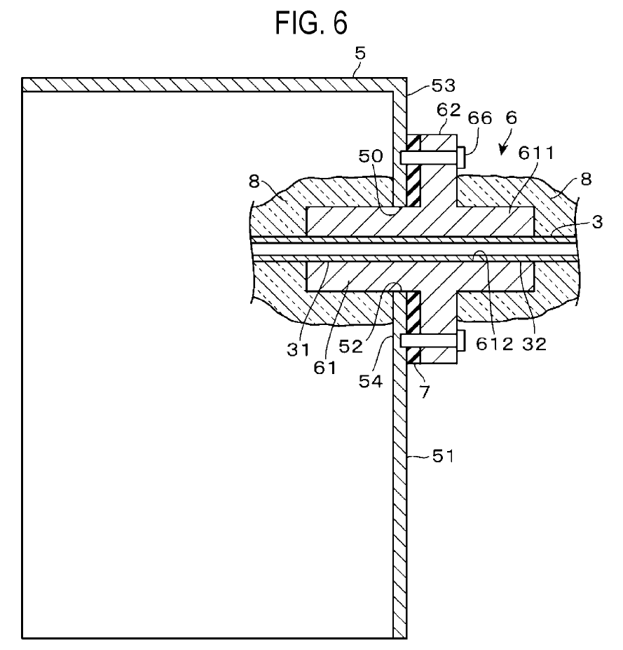

The present disclosure has been made in view of the above-described issues. Hereinafter, a first embodiment of the gas supply system 2 according to the present disclosure will be described with reference to FIGS. 6 to 8C, taking the processing gas supply pipe 3 as an example. In addition, the same reference numerals are given to components having the same configurations as those of the first and second comparative embodiments, and descriptions thereof are omitted.

As illustrated in FIG. 6, the processing gas supply pipe 3 made of, for example, stainless steel is inserted into the outer wall 51 of the gas box housing 5 so as to pass through the through-hole 52 substantially perpendicular to the outer wall 51. In the processing gas supply pipe 3, the pipe 3 in a region inside the gas box housing 5 is referred to as an inner pipe portion 31, and the pipe 3 in a region outside the gas box housing 5 is referred to as an outer pipe portion 32. The region inside the gas box housing 5 refers to a region inward than an inner wall surface 54 of the gas box housing 5.

### Block Member

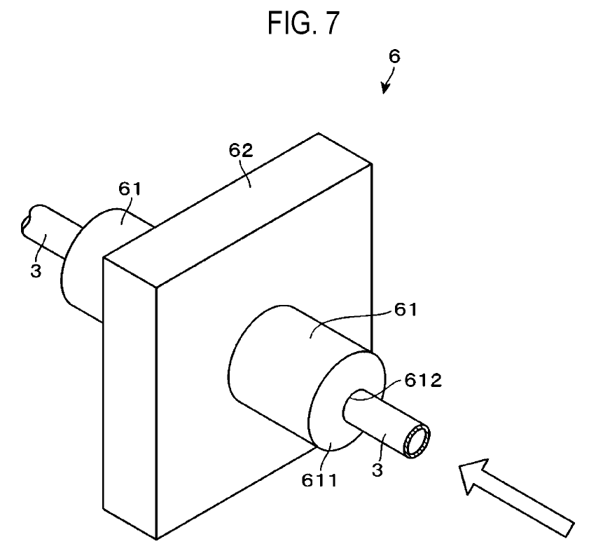

The block member 6 is provided in the through-hole 52 to block a gap 50 between the inner peripheral surface of the through-hole 52 and the outer peripheral surface of the pipe 3 passing through the through-hole 52. The block member 6 includes a pipe surrounding portion 61 and a flange portion 62, as illustrated in FIGS. 6 and 7 by way of example. The block member 6 is made of a material that has excellent thermal conductivity, allows the pipe surrounding portion 61 and the flange portion 62 to be formed integrally, and is capable of being brought into close contact with the pipe 3. Therefore, the block member 6 is suitably made of a metal, and is made, for example, of aluminum (Al).

The pipe surrounding portion 61 is configured to integrally surround the inner pipe portion 31 and the outer pipe portion 32, and is provided in the gap 50 between the through-hole 52 and the pipe 3 so as to fill the gap 50. As illustrated in FIG. 7, the pipe surrounding portion 61 in this example has a configuration in which a cylindrical body 611 has an opening 612 through which the pipe 3 (the inner pipe portion 31 and the outer pipe portion 32) is inserted. The cylindrical body 611 is arranged such that the longitudinal direction thereof extends along the axial direction of the pipe 3 (the direction indicated by an arrow in FIG. 7), and the opening 612 is formed so as to penetrate the cylindrical body 611 along the axial direction. The opening 612 is formed in conformity with the shape of the pipe 3 such that an inner peripheral surface thereof comes into close contact with outer peripheral surfaces of the inner pipe portion 31 and the outer pipe portion 32. Accordingly, in this example, the outer diameter of the pipe surrounding portion 61 and the inner diameter of the through-hole 52 are substantially the same.

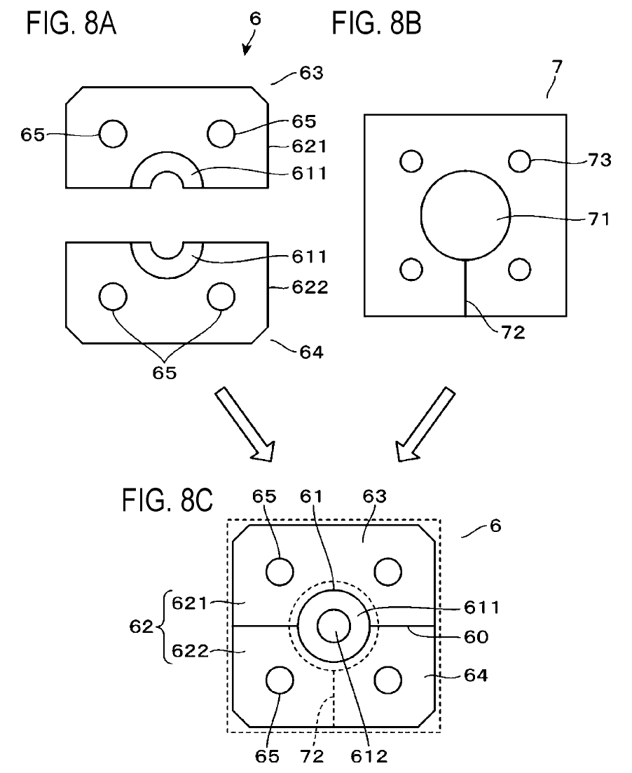

As illustrated in FIGS. 6 and 7, the flange portion 62 is provided, for example, at an intermediate position in the longitudinal direction of the pipe surrounding member 61 along an outer peripheral surface thereof. Further, as illustrated in FIGS. 7 to 8C, the flange portion 62 is formed, for example, in a rectangular plate shape when viewed in the pipe axial direction, and has a planar surface facing the outer wall surface 53 of the gas box housing 5. Then, the flange portion 62 is configured to block the gap 50 between the through-hole 52 and the pipe 3 by installing the planar surface on the outer wall surface 53 via a seal member 7 to be described later. The flange portion 62 in this example is provided substantially at the center of the pipe surrounding portion 61 in the longitudinal direction.

With this configuration, when the flange portion 62 is provided to the outer wall surface 53, one end of the pipe surrounding portion 61 is inserted into the interior of the gas box housing 5, and the other end thereof protrudes outward from the gas box housing 5. In this way, in the pipe 3 inserted into the through-hole 52 of the gas box housing 5, the inner pipe portion 31 and the outer pipe portion 32 are integrally surrounded by the pipe surrounding portion 61.

The block member 6 is configured to be dividable into a plurality of divided portions in the circumferential direction of the pipe 3. FIG. 8A is a side view of the block member 6 when viewed from the pipe axial direction. In this example, the block member 6 is composed of two divided portions 63 and 64 divided vertically, that is, an upper first divided portion 63 and a lower second divided portion 64. Screw holes 65 are formed in the flange portion 62 (a first flange portion 621 and a second flange portion 622) of the first and second divided portions 63 and 64 at positions outside a region in which the opening 612 is formed. Each screw hole 65 is a through-hole formed to be larger than a screw 66. In addition, the screw holes 65 are omitted from illustration in FIG. 7.

Then, the first divided portion 63 is positioned from above the pipe 3, and the first flange portion 621 is fixed to the outer wall surface 53 with the screw 66. The second divided portion 64 is positioned from below the pipe 3, and the second flange portion 622 is fixed to the outer wall surface 53 with the screw 66. Thereby, the block member 6 is constituted by the first divided portion 63 and the second divided portion 64, and the block member 6 is fixed to the outer wall surface 53 of the gas box housing 5 in a state where the pipe 3 is fastened from above and below. At this time, inner peripheral surfaces of the first and second divided portions 63 and 64 come into close contact with the outer peripheral surface of the pipe 3. Further, a lower end surface of the first divided portion 63 and an upper end surface of the second divided portion 64 also come into close contact with each other, and a contact surface 60 thereof is substantially parallel to the pipe axial direction.

In this way, an inner peripheral surface of the pipe surrounding portion 61 comes into close contact with the outer peripheral surfaces of the inner pipe portion 31 and the outer pipe portion 32, and the gap 50 between the through-hole 52 and the pipe 3 is blocked by the flange portion 62 provided around the pipe surrounding portion 61. Since the screw hole 65 of the flange portion 62 is formed as a through-hole, the divided portions 63 and 64 may be attached to the gas box housing 5 while adjusting positions thereof. In this example, by attaching the flange portion 62 to the gas box housing 5 with the screw 66, the block member 6 is fixed to the gas box housing 5, and the closeness between the pipe surrounding portion 61 and the pipe 3 is enhanced.

The size of the block member 6 is set according to the size of the pipe 3, and the nominal diameter of the pipe 3 may be, for example, a 1/2-inch size or 3/8-inch size. As an example of the size of the block member 6 when the pipe 3 has a 3/8-inch size, the length of the pipe surrounding portion 61 (the dimension in the pipe axial direction) is 32 mm, the thickness of the flange portion 62 (the dimension in the pipe axial direction) is 10 mm, and the vertical and horizontal dimensions of the flange portion 62 when viewed from the pipe axial direction are 40 mm x 40 mm.

### Seal Member

The above-described block member 6 is fixed to the outer wall surface 53 of the gas box housing 5 with the seal member 7 interposed between the outer wall surface 53 and the flange portion 62. The seal member 7 is formed in a rectangular shape similar to that of the flange portion 62 when viewed from the axial direction of the pipe 3, as illustrated in FIG. 8B, and is, for example, a packing made of, for example, a deformable material such as an elastic material having heat resistance, for example, fluoro-rubber.

The seal member 7 has, for example, a circular opening 71 at a position through which the pipe surrounding portion 61 passes. In this example, as illustrated in FIGS. 8A to 8C, the opening 71 is formed, for example, to be larger than the outer diameter of the pipe surrounding portion 61, for example. However, the opening 71 may be formed to have substantially the same size as the pipe surrounding portion 61, as long as the pipe surrounding portion 61 may pass therethrough. Further, the seal member 7 is formed with a slit 72 between an inner peripheral end of the opening 71 and an outer peripheral end of the seal member 7. For example, the slit 72 is formed from a lowermost position of the inner peripheral end of the opening 71 toward the outer peripheral end of the seal member 7 in a direction perpendicular to the pipe axial direction. Furthermore, the seal member 7 has a screw hole 73 for screwing the seal member 7 to the outer wall surface 53 of the gas box housing 5 at a position corresponding to the screw hole 65 of the flange portion 62. For example, the screw hole 73 is formed to be smaller than the screw hole 65 of the flange portion 62.

Such a seal member 7 is disposed between the outer wall surface 53 of the gas box housing 5 and the flange portion 62, and has a function of enhancing the airtightness between the outer wall surface 53 and the flange portion 62 when the flange portion 62 is screwed to the outer wall surface 53. Further, since the seal member 7 is deformable, the pipe surrounding portion 61 is mounted in the opening 71 so as to be kept in place in the opening 71 after the slit 72 is opened. After that, the slit 72 is closed, thereby ensuring the sealing performance thereof.

In this way, when the seal member 7 and the block member 6 are attached to the outer wall surface 53 of the gas box housing 5, as illustrated in FIG. 8C, the contact surface 60 between the divided portions 63 and 64 of the flange portion 62 and the slit 72 of the seal member 7 are arranged so as to be offset from each other when viewed from the axial direction of the pipe 3. In this way, since the contact surface 60 between the divided portions 63 and 64 and the position of the slit 72 do not overlap with each other, the airtightness of the gas box housing 5 is further ensured. As described above, the flange portion 62 and the seal member 7 are formed to have substantially the same shape, but in FIG. 8C, the seal member 7 is illustrated slightly larger for convenience of illustration.

### Heating Mechanism

Further, the gas supply system 2 includes a heating mechanism. The heating mechanism is configured, for example, with a tape heater 8, and the tape heater 8 is wound around the pipe surrounding portion 61 located outward than the flange portion 62 when viewed from the gas box housing 5. Further, the tape heater 8 is also wound around the pipe 3 outward than the pipe surrounding portion 61 surrounding the outer pipe portion 32.

Furthermore, the tape heater 8 is wound around the pipe surrounding portion 61 located inside the gas box housing 5, and is also wound around the pipe 3 inward than the pipe surrounding portion 61 surrounding the inner pipe portion 31. As illustrated in FIG. 6, the tape heater 8 in this example is wound only around a part of the pipe surrounding portion 61 and around the pipe 3 upstream of and downstream of the pipe surrounding portion 61. That is, in this example, the tape heater 8 is wound around the cylindrical body 611 located before and after the flange portion 62, while the tape heater 8 is not wound around the flange portion 62.

The pipe surrounding portion 61 is made of aluminum having good thermal conductivity, and the inner peripheral surface of the pipe surrounding portion 61 and the outer peripheral surface of the pipe 3 are provided in close contact with each other. Thereby, the pipe 3 in a region surrounded by the pipe surrounding portion 61 is heated by heat transfer from the pipe surrounding portion 61 heated by the tape heater 8. As a result, the entire block member 6 is heated by heat transfer from the pipe 3, around which the tape heater 8 is wound, upstream of and downstream of the pipe surrounding portion 61.

On the other hand, the tape heater 8 is not able to be directly wound around the pipe 3 (the inner pipe portion 31 and the outer pipe portion 32) surrounded by the pipe surrounding portion 61 of the block member 6. In particular, the pipe 3 is spaced apart from the tape heater 8 in a region thereof in which the flange portion 62 is provided and in a region thereof surrounded by the through-hole 52 of the gas box housing 5. These regions of the pipe 3 are sufficiently heated by the block member 6 that is heated as a whole. The heating temperature of the pipe 3 is set to, for example, a temperature equal to or higher than a vaporization temperature of a processing gas, and is, for example, 100 degrees C to 200 degrees C although it varies depending on the type of the processing gas.

As described above, a method of attaching the pipe while maintaining the airtightness of the gas box housing 5 using the block member 6 has been described by taking the processing gas supply pipe 3 as an example. On the other hand, as described with reference to FIG. 1, in the gas supply system 2, the supply pipe 3A and the first exhaust pipe 3B are installed so as to pass through through-holes 52 formed in the gas box housing 5. Furthermore, although not illustrated in FIG. 1, the first pipe 3C and the second pipe 3D illustrated in FIG. 3 are also installed so as to pass through through-holes 52 formed in the gas box housing 5. In order to maintain the airtightness of the gas box housing 5, these pipes 3A, 3B, 3C and 3D may also be installed using the block member 6. In this case, the tips of the pipes 3A and 3B do not necessarily need to extend further into the interior of the gas box housing 5 from regions thereof surrounded by the pipe surrounding portion 61, as illustrated by the example of the supply pipe 3A and the first exhaust pipe 3B in FIG. 1. When viewed from the interior side of the gas box housing 5, an end of the pipe surrounding portion 61 of the block member 6 may flush with ends of the inner pipe portions 31 of these pipes 3A and 3B.

In this example, the pipes 3A, 3B and 3D through which the inert gas is supplied or exhausted and the pipe 3C through which the room-temperature liquid 40 flows do not cause issues such as solidification and particle generation due to a decrease in temperature, and therefore do not necessarily need to be heated. Accordingly, the tape heater 8 is not wound around these pipes 3A, 3B, 3C and 3D. When the pipes are not heated in this manner, the tape heater 8 serving as a heating mechanism needs not to be wound around the outer peripheral surface of the pipe surrounding portion 61 of the block member 6.

By the way, in the example of the gas supply system 2 illustrated in FIG. 1, the tape heater 8 is also wound around the processing gas supply pipe 3 upstream of and downstream of the region thereof surrounded by the pipe surrounding portion 61, such that the entire processing gas supply pipe 3 is heated. Then, the processing gas supply pipe 3 passes through a through-hole (not illustrated) formed in the outer housing 42 and is inserted into the through-hole 52 of the gas box housing 5. At this time, no block member 6 is provided at a connection point between the outer housing 42 and the pipe 3. Accordingly, the through-hole of the outer housing 42 is configured to be blocked by the tape heater 8 wound around the pipe 3, similarly to the case described with reference to the first comparative embodiment of FIG. 4. In addition, the block member 6 and the tape heater 8 may be provided in the same manner as in the gap 50 when it is necessary to ensure the airtightness at a connection point between the outer housing 42 and the pipe 3.

According to the embodiment described above, in the gas supply system 2 in which the pipe 3 is provided so as to pass through the through-hole 52 of the gas box housing 5, the block member 6 is provided to block the gap 50 between the through-hole 52 and the pipe 3. With this configuration, a fluid may be discharged from the gas box housing 5 via the pipe 3 while maintaining the airtightness of the gas box housing 5.

Here, the block member 6 includes the pipe surrounding portion 61 configured to integrally surround the inner pipe portion 31 and the outer pipe portion 32 of the pipe 3 (3A, 3B, 3C, and 3D). The block member 6 is fixed to the gas box housing 5 in a state where the pipe surrounding portion 61 is inserted into the gap 50 between the through-hole 52 and the pipe 3. Since the pipe surrounding portion 61 is provided so as to fill the gap 50 in this manner, the gap 50 may be sealed with high accuracy, thereby preventing gas leakage from the gas box housing 5.

Further, the block member 6 includes the flange portion 62, and the flange portion 62 is installed and fixed to the outer wall surface 53 of the gas box housing 5. The flange portion 62 is provided along the outer peripheral surface of the pipe surrounding portion 61. Therefore, even if a slight gap is formed between the inner peripheral surface of the through-hole 52 and the outer peripheral surface of the pipe surrounding portion 61 when the pipe surrounding portion 61 is inserted into the gap 50, the gap 50 may be blocked by the flange portion 62, thereby further improving the airtightness of the gas box housing 5.

Furthermore, since the through-hole 52, the pipe 3, and the block member 6 are easier to dimensionally control than members made of flexible materials, there is a less risk of a variation in airtightness. From this viewpoint, the gap 50 may be sealed with high accuracy. In addition, since the pipe surrounding portion 61 and the flange portion 62 may be formed integrally, the number of components required to ensure the airtightness of the gas box housing 5 may be reduced. Thereby, management to prevent a variation in airtightness is facilitated, and a reduction in manufacturing cost may be achieved.

Furthermore, the block member 6 is divided into a plurality of divided portions 63 and 64, and the divided portions 63 and 64 are installed to surround the pipe 3 from the outside of the pipe 3. The pipe 3 may actually be provided with a joint portion, the outer diameter of which is larger than that of the pipe 3. Therefore, in a case of the integrally formed block member 6, it may be difficult to position the pipe surrounding portion 61 at a position where the pipe 3 passes through the through-hole 52 after passing around the arrangement position of the joint portion. In this respect, by installing the divided block member 6 from the outside of the pipe 3, the block member 6 may be easily positioned in close contact with the pipe 3.

Further, in the processing gas supply pipe 3, the pipe 3 in its region surrounded by the pipe surrounding portion 61 is heated by heat transfer from the pipe surrounding portion 61 heated by the tape heater 8. Since even the pipe 3 inserted into the through-hole 52 is also heated in this manner, liquefaction or solidification of a gas flowing in the interior of the pipe 3 may be prevented, thereby preventing generation of particles. At this time, the pipe 3 may be heated more efficiently when the block member 6 is made of a metal having good thermal conductivity. Furthermore, in this example, since the tape heater 8 is not wound around a part of the flange portion 62, downsizing may be achieved as compared with a configuration in which the tape heater 8 is wound around the entire block member 6.

Here, in the above-described configuration, the block member 6 is not provided at a connection point between the outer housing 42 and the processing gas supply pipe 3, but the interior of the outer housing 42 is exhausted by the exhauster 26 via the second exhaust pipe 261. Therefore, even if a gap is formed between an opening of the outer housing 42 and the pipe 3 and an atmosphere outside the gas box 4 is introduced into the outer housing 42 via the gap, there is a less risk of gas leakage from the outer housing 42 because the atmosphere is exhausted by the exhauster 26.

### Second Embodiment

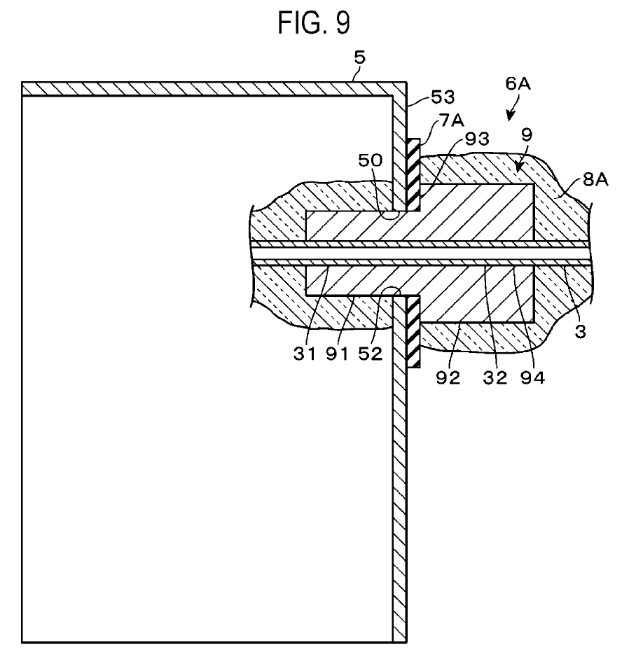

Next, a second embodiment of a gas supply system according to the present disclosure will be described with reference to FIG. 9. A block member 6A in this example includes a pipe surrounding portion 9 having a functions as a flange portion. The pipe surrounding portion 9 includes a first pipe surrounding portion 91 that is inserted into the through-hole 52 when the block member 6A is attached to the gas box housing 5, and a second pipe surrounding portion 92 that is positioned outside the gas box housing 5.

The first pipe surrounding portion 91 is a pipe portion surrounding the inner pipe portion 31, and the outer diameter thereof is substantially the same as that of the through-hole 52. Further, the second pipe surrounding portion 92 is a pipe portion surrounding the outer pipe portion 32, and the outer diameter thereof is larger than that of the through-hole 52. Thereby, a connection portion between the first pipe surrounding portion 91 and the second pipe surrounding portion 92 increases in diameter stepwise at the outside of the gas box housing 5, forming an enlarged-diameter portion 93. The enlarged-diameter portion 93 faces the outer wall surface 53 of the gas box housing 5, thus functioning as a flange portion.

The pipe surrounding portion 9 is provided, at the center thereof when viewed from the pipe axial direction, with an opening 94 through which the pipe 3 passes, the opening 94 extending across the first and second pipe surrounding portions 91 and 92. Then, an inner peripheral surface of the opening 94 comes into close contact with the outer peripheral surface of the pipe 3 (the inner pipe portion 31 and the outer pipe portion 32) and is configured to integrally surround that the inner pipe portion 31 and the outer pipe portion 32. Then, in a state where a seal member 7A is disposed between the enlarged-diameter portion 93 of the second pipe surrounding portion 92 and the outer wall surface 53 of the gas box housing 5, the second pipe surrounding portion 92 is screwed to the outer wall surface 53 with screws (not illustrated).

A tape heater 8A, which serves as a heating mechanism, is wound around the first and second pipe surrounding portions 91 and 92. The seal member 7A in this example is formed to be larger than the second pipe surrounding portion 92, and further larger than the outer diameter of the tape heater 8A wound around the second pipe surrounding portion 92 when viewed from the pipe axial direction.

In this example, the block member 6A is configured to block the gap 50 between the through-hole 52 and the pipe 3 by filling the gap 50 with the first pipe surrounding portion 91. Further, the block member 6A is heated by the tape heater 8A provided around the pipe surrounding portions 91 and 92, and heat of the pipe surrounding portions 91 and 92 is transferred to the region of the pipe 3 surrounded by the pipe surrounding portions 91 and 92, thereby heating the pipe 3 in that region. Other configurations are the same as those of the first embodiment, and the same reference numerals are given to the same components, and descriptions thereof are omitted. In this embodiment as well, the airtightness of the gas box housing 5 may be ensured, and the pipe 3 may be heated.

In the above description, the processing gas supply pipe 3 and the first exhaust pipe 3B have been described as examples of pipes through which a fluid flowing out of the gas box housing 5 flows, and the supply pipe 3A and the first pipe 3C have been described as examples of pipes through which a fluid flowing into the gas box housing 5 flows. These fluids flowing through the pipes arranged using the block member 6 or 6A of the present disclosure include gases and liquids. Further, although a configuration in which the pipes 3A, 3B, 3C and 3D are not heated has been described, a heating mechanism may also be provided for these pipes as needed. For example, it is assumed that a gas precursor that is solid at room temperature is heated and liquefied, and a liquid precursor is supplied from the reservoir 27 to the precursor container 41 via the first pipe 3C. In this case, a heating mechanism for heating the first pipe 3C may be additionally provided in order to prevent solidification of the liquid precursor, and the first pipe 3C may be installed to the through-hole 52 of the gas box housing 5 using the block member 6 or 6A.

Further, a configuration in which the block member includes only the pipe surrounding portion may be conceived. In this case, the pipe surrounding portion fills the gap between the through-hole and the pipe, thereby blocking the gap. Furthermore, when the block member includes the flange portion, the pipe surrounding portion does not necessarily need to be formed in a shape that completely fills the gap. Furthermore, the block member may have any shape as long as it blocks the gap between the through-hole and the pipe, and the shapes of the pipe surrounding portion and the flange portion are not limited to the above-described configurations and may be appropriately modified.

Furthermore, the gas box of the gas supply system is not limited to the above-described configuration, and may have any configuration as long as it includes the gas box housing and the precursor container that accommodates a gas precursor. Furthermore, the gas precursor is not limited to a liquid, and for example, a gas precursor that is solid at room temperature such as tungsten chloride (WCl₆) may also be used.

Further, as described above, the heating mechanism for heating the block member is not necessarily required, and even when provided, the shape of the heating mechanism may be appropriately modified. Further, the heating mechanism for heating the block member 6 may include only the tape heater 8 wound around a portion of the pipe 3 outward than the pipe surrounding portion 61 surrounding the outer pipe portion 32. In this case, the tape heater 8 is not wound around the pipe surrounding portion 61 itself, but the pipe surrounding portion 61 is raised in temperature by heat transfer from the pipe 3 heated by the tape heater 8. By adopting such a configuration in which the tape heater 8 is not wound around the pipe surrounding portion 61, a more compact configuration may be achieved. Further, the heating mechanism is not limited to the tape heater, and a mantle heater may be used.

The block member 6 of the present disclosure does not need to be applied to all pipes through which a fluid flowing into the gas box housing 5 from outside, or all pipes through which a fluid flowing out of the gas box housing 5 to the outside flows. It is sufficient that the block member 6 is applied to at least one of pipes installed in the gas box housing 5 through which inflow and outflow fluids flow. Further, the block member 6 of the present disclosure may also be applied to pipes installed in the outer housing 42.

Although a wafer has been described as an example of a substrate, the substrate processed in a processing container is a substrate for manufacturing a semiconductor. Such a semiconductor manufacturing substrate includes not only a wafer but also a substrate for manufacturing a flat panel display, a substrate for manufacturing an exposure mask used in photolithography, and a dummy substrate that is processed for testing or setting processing parameters in a substrate processing apparatus.

According to the present disclosure, it is possible to cause a fluid to flow into or out of a gas box housing via piping while maintaining the airtightness of the gas box housing.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas supply system comprising:
a gas box housing in which a precursor container accommodating a gas precursor is disposed;
at least one pipe passing through a through-hole in the gas box housing, through which a fluid flowing into the gas box housing from outside flows, or a fluid flowing out of the gas box housing to the outside flows; and
a block member installed in the through-hole and including a pipe surrounding portion configured to integrally surround an inner pipe portion that is a portion of the pipe inside the gas box housing and an outer pipe portion that is a portion of the pipe outside the gas box housing,
wherein, in a state where the pipe surrounding portion is inserted into a gap between an inner peripheral surface of the through-hole and an outer peripheral surface of the pipe passing through the through-hole, the block member is fixed to the gas box housing to block the gap.

2. The gas supply system of claim 1, further comprising a heating mechanism configured to heat the block member,
wherein the pipe in a region surrounded by the pipe surrounding portion is heated by heat transfer from the pipe surrounding portion heated by the heating mechanism.

3. The gas supply system of claim 2, wherein the heating mechanism is a tape heater wound around the pipe surrounding portion in a region surrounding the outer pipe portion.

4. The gas supply system of claim 2, wherein the heating mechanism is a tape heater wound around the pipe at a position further outward than the pipe surrounding portion in a region surrounding the outer pipe portion when viewed from the gas box housing, and
wherein the pipe surrounding portion is configured to heat the pipe in the region surrounded by the pipe surrounding portion by being raised in temperature by heat transfer from the pipe heated by the tape heater.

5. The gas supply system of claim 1, wherein the block member is configured to block the gap by filling the gap with the pipe surrounding portion.

6. The gas supply system of claim 1, wherein the block member includes a flange portion provided along an outer peripheral surface of the pipe surrounding portion and configured to block the gap by being attached to an outer wall surface of the gas box housing.

7. The gas supply system of claim 6, further comprising a seal member disposed between the flange portion and the outer wall surface.

8. The gas supply system of claim 7, wherein the block member is configured to be dividable into a plurality of divided portions along a circumferential direction of the pipe.

9. The gas supply system of claim 8, wherein the seal member is made of a deformable material, and includes an opening, through which the pipe passes, and a slit formed between an inner peripheral end of the opening and an outer peripheral end of the seal member.

10. The gas supply system of claim 9, wherein, in a state where the seal member is disposed between the flange portion and the outer wall surface, a contact surface between the plurality of divided portions and the slit of the seal member are arranged so as to be offset from each other when viewed from an axial direction of the pipe.

11. A semiconductor manufacturing apparatus comprising:
a processing container configured to accommodate and process a substrate; and
the gas supply system of claim 1,
wherein the gas supply system includes, as the pipe, a processing gas supply pipe configured to supply a processing gas obtained from the gas precursor from the precursor container to the processing container.
